(19) United States
(12) Patent Application Publication
(10) Pub. No.: US 2009/0142915 A1
(43) Pub. Date: Jun. 4, 2009

(54) GATE STRUCTURE AND METHOD OF FORMING THE SAME

(76) Inventor: Weize Xiong, Davis, CA (US)

Correspondence Address: CYPRESS SEMICONDUCTOR CORPORATION, 198 CHAMPION COURT, SAN JOSE, CA, 95134-1709, US

(21) Appl. No.: 11/950,076

(22) Filed: Dec. 4, 2007

(51) Int. Cl. H01L 21/441

(52) U.S. Cl. 438/595; 257/E21.477

(57) ABSTRACT

A semiconductor device includes a semiconductor substrate, a dielectric layer on the substrate, and a gate on the dielectric layer. The gate has first and second ends containing a first material, a middle region between the first and second ends containing a second material. The first material has a different work function than the second material.

### BACKGROUND

The present invention relates to semiconductor structures, semiconductor devices and methods of making the same.

In MOSFET devices, gate electrodes (gates) have been made from mid-band gap materials, such as TiN and SiGe, rather than the typical doped polycrystalline silicon (poly). Mid-band gap materials are metallic materials that have a work function near the mid-gap of Si (about 4.6 eV). These materials are described in “Metal Gates for Advanced CMOS Technology” Maiti, et al. SPIE Vol. 3881, SPIE Conference on Microelectronic Device Technology III, Santa Clara, Calif., September 1999 (pp. 46-57). These gate electrodes have been used in both bulk and silicon-on-insulator (SOI) devices, in order to reduce poly depletion effects and boron penetration problems associated with dual poly gate MOSFETs. Poly depletion effects occur when a very thin gate oxide is used; the bottom portion of the gate is depleted of carriers, causing it to act as an insulator, functionally making the gate oxide thicker. This depletion occurs in poly gates, but does not occur in metal gates.

A disadvantage of these mid-band gap materials is that they produce a MOSFET with a high threshold voltage (Vt), retarding the device drive current. This can be compensated by a reduction in the channel doping, but then drain induced barrier lowering occurs (DIBL), and leakage is significant.

It would be desirable to take advantage of different work function materials in a MOSFET gate, while eliminating or mitigating the disadvantages.

A dual material gate field effect transistor has been described (Long, et al. “Dual Material Gate Field Effect Transistor (DMGFET)” IEDM 97 (p. 549-52)). This device is illustrated in FIG. 1. The transistor 2, includes a gate 6, on a gate oxide 22, which itself is on a semiconductor substrate 4. A source 8, and a drain 10, are in the substrate. The gate is made of two different material, 14 and 16, place side-by-side, with the work function of the first material 14 being larger than the work function of the second material 16. This structure is not symmetric. This gate structure takes advantage of the material work function differences in such a way that the threshold voltage near the source is more positive than that near the drain, resulting in a more rapid acceleration of charge carriers in the channel and a screening effect to suppress short channel effects. However, this dual material gate was prepared by tilt evaporation, which is not practical in large-scale VLSI processes. Furthermore, controlling the length fraction of the two materials is difficult.

### BRIEF SUMMARY

In a first aspect, the present invention is a semiconductor device, including a semiconductor substrate, a dielectric layer on the substrate, and a gate on the dielectric layer. The gate has first and second ends containing a first material, a middle region between the first and second ends containing a second material. The first material has a different work function than the second material.

In a second aspect, the present invention is a CMOS device, including the first semiconductor device described above, and a second semiconductor device, including a second dielectric layer on the substrate, and a second gate on the dielectric layer. The second gate has third and fourth ends containing a third material, and a second middle region between the third and fourth ends containing the second material.

In a third aspect, the present invention is a method of making a semiconductor structure, including forming a gate on a dielectric layer. The gate has first and second ends containing a first material, and a middle region between the ends containing a second material. The first material has a different work function than the second material, and the dielectric layer is on a semiconductor substrate.

In a fourth aspect, the present invention is a method of making a semiconductor device, including making a semiconductor structure by the above method; and forming a semiconductor device from the structure.

In a fifth aspect, the present invention is a method of making an electronic device, including making a semiconductor device by the above method; and forming an electronic device containing the semiconductor device.

The term “work function” of a material means the work function of the material as a gate electrode extracted from a MOS structure using high frequency capacitance-voltage, by the procedure described in “Electrical characterization of ZrN,” Krusin-Elbaum et al., Mat. Res. Soc. Symp. Proc., vol. 171, p. 351, 1986.

### BRIEF DESCRIPTION OF THE DRAWINGS

Various other objects, features and attendant advantages of the present invention will be more fully appreciated as the same becomes better understood from the following detailed description when considered in connection with the accompanying drawings in which like reference characters designate like or corresponding parts throughout the several views and wherein:

FIG. 1 illustrates a dual material gate field effect transistor;

FIGS. 2-5 illustrate how the embodiment of FIG. 6 may be prepared;

FIG. 6 shows a first embodiment of the present invention;

FIGS. 7 and 8 illustrate how the embodiment of FIG. 9 may be prepared;

FIG. 9 shows a second embodiment of the present invention;

FIGS. 10-13 illustrate how the embodiment of FIG. 14 may be prepared; and

FIG. 14 shows a third embodiment of the present invention.

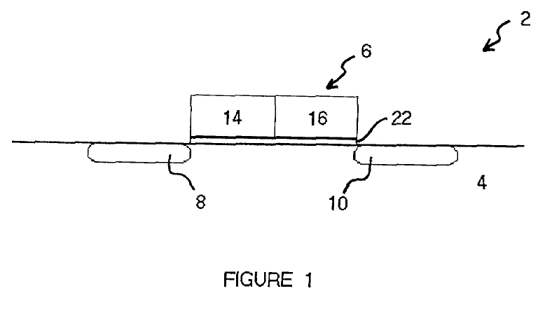

### DETAILED DESCRIPTION

The present invention includes a gate having at least two materials. This gate takes advantage of the work function difference of the materials, creating a cross-channel work function difference, resulting in a MOSFET with lower I-off (leakage current) at a given I-on (current during operation), or vise versa.

The gate of the present invention has a first material on both ends toward the source/drain regions, and a second material between the two ends, in a middle region. Preferably, the gate is symmetric, having middle region include the center of the gate, with both ends of about equal length. Preferably, the gate includes two materials, each with a different work function. The material may be any metallic or conductive material, such as metals and alloys, doped semiconductors, and metallic compounds. Examples of metals and alloys include Al, Cu, Au, Ag, W, Ti, Zr, Mo, Pt, Ir, Pd, Mg, Ta, Nb, Cr, Ni, and alloys thereof. Doped semiconductors include Si, Ge, SiGe, and mixture and alloys thereof; III-V semiconductors such as GaAs and InP, and mixtures and alloys thereof; and II-VI semiconductors such as ZnO and CdS, and mixtures and alloys thereof. Examples of metallic compounds include nitrides such as TiN, TaN, NbN, ZrN, MoN and WN; silicides such as WSi, TiSi₂, and MoSi₂; oxides such as TiOₓ and ZrOₓ; and mixtures and alloys thereof. More preferably, the first material is p-doped poly or n-doped poly, for PMOS or NMOS transistors, respectively, and the second material is TiN or WSi.

Preferably, the work function of the first material is smaller than the work function of the second material, in an n-channel transistor; in an p-channel transistor, the work function of the second material is preferably smaller than that of the second material. A CMOS device, which includes both p-channel and n-channel transistors, preferably has the smaller work function material as the first material in the n-channel transistors and the greater work function material as the first material in the p-channel transistors. Preferably, the work function of both materials is 4.17-5.2 eV. Preferably, the difference in work function between the first and second materials is at least 0.1 eV, more preferably at least 0.2 eV, even more preferably at least 0.4. The difference in work function between the first and second materials is preferably 0.1-1.1 eV, more preferably 0.2-0.7 eV, even more preferably 0.4-0.5 eV. For p-channel transistors, the work function of the second material is preferably at least 4.17 eV. For n-channel transistors, the work function of the second material is preferably at most 5 eV.

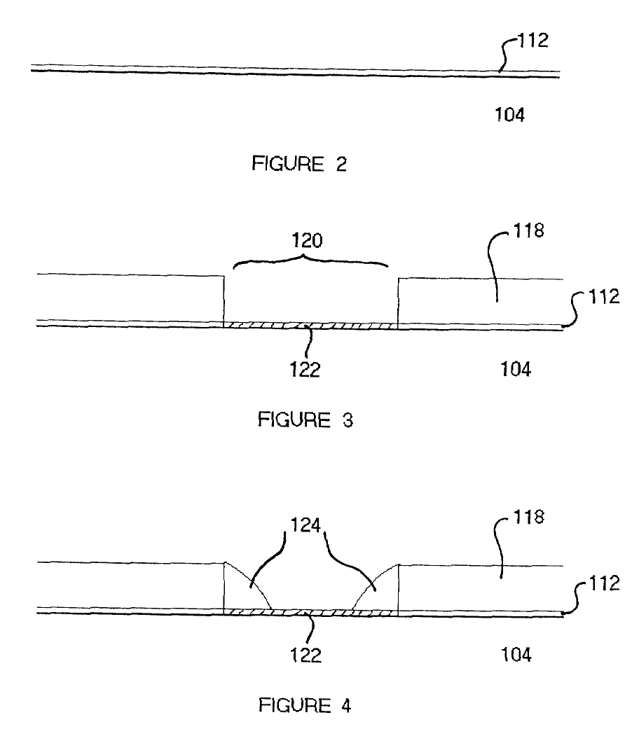

A first embodiment of the invention is shown in FIG. 6. The transistor 102, includes a gate 106 on a gate dielectric 122, all on a semiconductor substrate 104. The substrate includes two source/drain regions 108 and 110. The gate includes a first material 124 on the ends closest to the source/drain regions, and a second material 126, between the ends. Both the first material and the second material are on the gate dielectric. This first embodiment may be prepared as illustrated in FIGS. 2-5.

FIG. 2 shows a structure including a substrate 104, having a dielectric layer 112. A sacrificial pad layer 118 is formed on the dielectric layer, and patterned to form a gate opening 120. Preferably, the dielectric layer 112 exposed in the gate opening is removed and reformed to form a gate dielectric layer 122; however, the original dielectric layer 112 may serve as the gate dielectric layer. This results in the structure illustrated in FIG. 3.

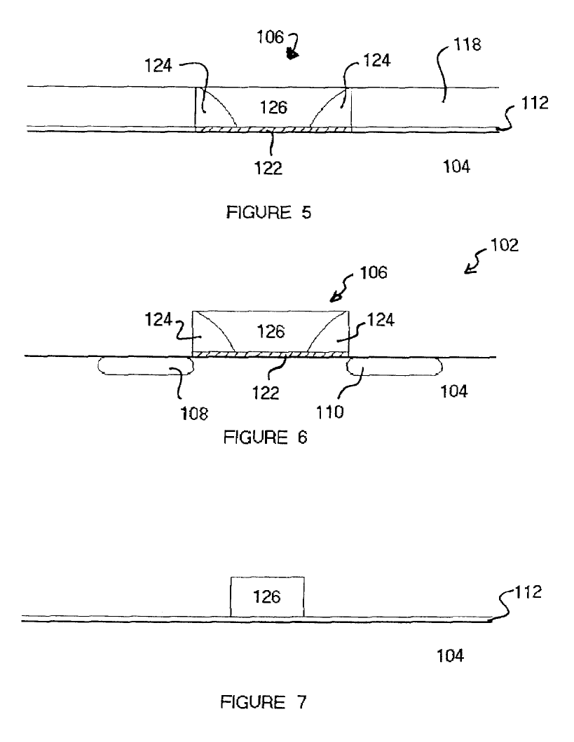

Next, a layer of the first material 124 is applied on this structure, and etched to form two spacer-shaped structure on both sides of gate opening 120, on gate dielectric 122, as shown in FIG. 4. A layer of the second material 126 is applied on this structure, and chemical-mechanical polishing (CMP) is used to level the surface to the top of the sacrificial pad layer 118, as shown in FIG. 5. This completes formation of the gate 106, which includes ends of the first material 124 and a center of the second material 126 on the gate dielectric 122. The sacrificial pad layer 118 may be removed, and the remaining parts of the transistor or semiconductor device may be formed. Finally, the semiconductor device may be incorporated into an electronic device. In all embodiments, parts of the semiconductor device, such as source/drain regions, may be formed before, after, or during, the formation of the gate.

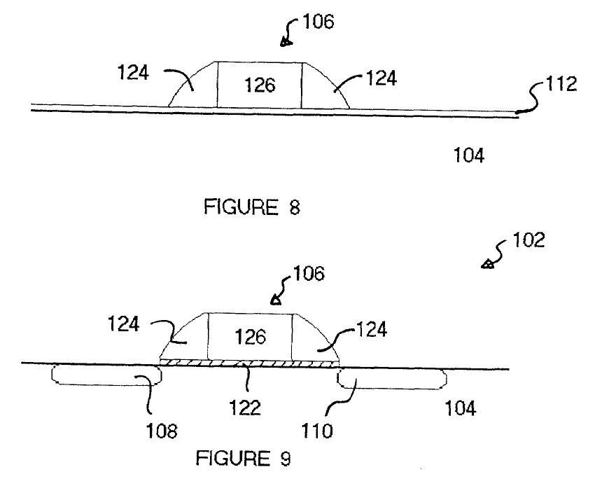

A second embodiment of the invention is shown in FIG. 9. Only the gate differs in this figure as compared with FIG. 6. The gate 106 includes a first material 124 on the ends closest to the source/drain regions, and a second material 126, between the ends. Both the first material and the second material are on the gate dielectric. The first material on the ends is in the form of two spacer-shaped structures. This structure may be formed as illustrated in FIGS. 7 and 8.

In FIG. 7, the second material 126 is on a dielectric layer 112, which is on a semiconductor substrate 104. This structure is formed as an ordinary gate would be formed in typically semiconductor devices. Next, a layer of the first material 124 is applied on the structure, and etched, to form spacer-shaped ends on the second material 126. This results in a gate 106 as illustrated in FIG. 8. The remaining parts of the transistor or semiconductor device may then be formed.

A third embodiment of the invention is shown in FIG. 14. Only the gate differs in this figure as compared with FIG. 6. The gate 106 includes a first material 124 on the ends closest to the source/drain regions, and a second material 126, between the ends. Both the first material and the second material are on the gate dielectric. Unlike FIG. 6, the second material 126 is not as thick as the first material 124, and is capped with an etch mask 128 that is preferably conductive, to the thickness of the first material. This conductive material may be any material that is conductive and that will serve as an etch mask for the second material. The conductive material may be the same as the first material. This structure may be formed as illustrated in FIGS. 3 and 10-13.

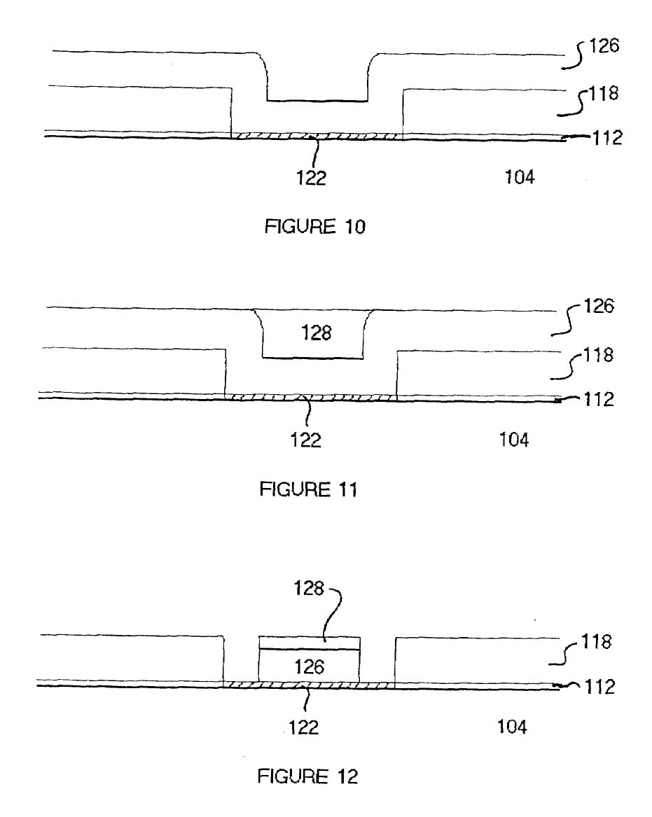

The structure shown in FIG. 3 has been described. A layer of the second material 126 is applied on this structure, to form the structure shown in FIG. 10. Next, a layer of the etch mask 128 is applied on the structure; this layer may then optionally be CMP to the top of the second material 126, to form the structure shown in FIG. 11, followed by etching the second material 126. Alternatively, the CMP may be preformed to the top of the sacrificial pad layer 118, followed by etching the second material 126, to form the structure shown in FIG. 12.

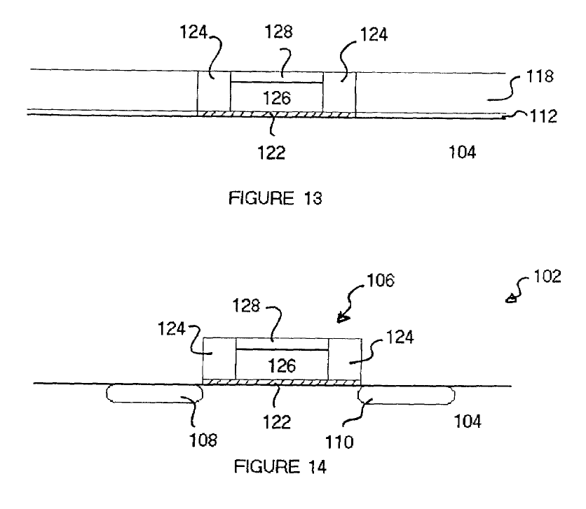

Next, a layer of the first material 124 is applied to the structure, filling in the gaps between the second material 126 and the sacrificial pad layer 118. The structure is then CMP to the top of the sacrificial pad layer 118 to form the structure shown in FIG. 13. The sacrificial pad layer 118 may be removed, and the remaining parts of the transistor or semiconductor device may be formed.

The individual processing steps for use in the present invention are well known to those of ordinary skill in the art, and are also described in Encyclopedia of Chemical Technology, Kirk-Othmer, Volume 14, pp. 677-709 (1995); Semiconductor Device Fundamentals, Robert F. Pierret, Addison-Wesley, 1996; Wolf, Silicon Processing for the VLSI Era, vols. 1-3, Lattice Press, 1986, 1990, 1995 (vols 1-3, respectively), and Microchip Fabrication 3rd. edition, Peter Van Zant, McGraw-Hill, 1997.

The dielectric layer and the gate dielectric layer may be made from any dielectric material conventionally known to those of ordinary skill in the art. Examples include conventional oxides, nitrides, oxynitrides, and other dielectrics, such as borophosphosilicate glass (BPSG), borosilicate glass (BSG), phosphosilicate glass, spin-on glass (SOG), silicon nitride, silicon oxide, P-doped silicon oxide (P-glass), for example SiO₂, Si₃N₄, Al₂O₃, SiOₓN_{y}, Ta₂O₅, TiO₂, etc. The term “oxide” refers to a metal oxide conventionally used to isolate electrically active structures in an integrated circuit from each other, typically an oxide of silicon and/or aluminum (e.g., SiO₂ or Al₂O₃, which may be conventionally doped with fluorine, boron, phosphorous or a mixture thereof; preferably SiO₂ or SiO₂ conventionally doped with 1-12 wt % of phosphorous and 0-8 wt % of boron). Preferably, the dielectric layer and the gate dielectric layer are formed from SiO₂ or Si₃N₄ The sacrificial pad layer may be formed from the same choices of material as the dielectric layer and the gate dielectric layer, as well as any metallic or conductive material, or any semiconductor material, as long as it will serve as a stop layer for CMP of the first material and/or the second material. Preferably, the sacrificial pad layer is formed from SiO₂ or Si₃N₄. The substrate may typically be a semiconductor material conventionally known by those of ordinary skill in the art. Examples include silicon, gallium arsenide, germanium, gallium nitride, aluminum phosphide, and alloys such as Si₁₋ₓGeₓ and AlₓGa₁₋ₓAs, where 0≦x≦1. Many others are known, such as those listed in Semiconductor Device Fundamentals, on page 4, Table 1.1 (Robert F. Pierret, Addison-Wesley, 1996). Preferably, the semiconductor substrate is silicon, which may be doped or undoped.

The structures of the present invention may be incorporated into a semiconductor device such as an integrated circuit, for example a memory cell such as an SRAM, a DRAM, an EPROM, an EEPROM etc.; a programmable logic device; a data communications device; a clock generation device; etc. Furthermore, any of these semiconductor devices may be incorporated in an electronic device, for example a computer, an airplane or an automobile.

Obviously, numerous modifications and variations of the present invention are possible in light of the above teachings. It is therefore to be understood that within the scope of the appended claims, the invention may be practiced otherwise than as specifically described herein.

1-10. (canceled)

11. A method of making a semiconductor structure, comprising:
forming a gate on a dielectric layer;
wherein said gate has first and second ends comprising a first material, and a middle region between said ends comprising a second material,
said first material has a different work function than said second material, and
said dielectric layer is on a semiconductor substrate.

12. The method of claim 11, wherein a difference between the work functions of the first and second materials is at least 0.1 eV.

13. The method of claim 12, wherein the difference between the work functions of the first and second materials is at least 0.2 eV.

14. The method of claim 13, wherein the difference between the work functions of the first and second materials is at least 0.4 eV.

15. The method of claim 13, wherein the difference between the work functions of the first and second materials is 0.2 to 0.7 eV.

16. The method of claim 13, wherein the first material comprises polycrystalline silicon.

17. The method of claim 13, wherein said forming said gate comprises:
forming said first and second ends; and
forming said middle region.

18. The method of claim 17, further comprising:
forming a sacrificial pad layer; followed by said forming said gate; followed by removing said sacrificial pad layer.

19. The method of claim 18, wherein said forming said middle region comprises:
forming a layer of said second material on said substrate; followed by chemical mechanical polishing said second material.

20. The method of claim 19, wherein said first material comprises polycrystalline silicon.

21. A method of making a semiconductor device, comprising:
making a semiconductor structure by the method of claim 11; and
forming a semiconductor device from said structure.

22. A method of making an electronic device, comprising:
making a semiconductor structure by the method of claim 21; and
forming a semiconductor device from said structure.

23. A semiconductor structure prepared by the method of claim 11.
